(19) United States
(12) Patent Application Publication
(10) Pub. No.: US 2010/0032198 A1
(43) Pub. Date: Feb. 11, 2010

(54) CIRCUIT MODULE

(76) Inventor: Hirobumi Inoue, Tokyo (JP)

Correspondence Address: Mr. Jackson Chen, 6535 N. STATE HWY 161, IRVING, TX, 75039, US

(21) Appl. No.: 12/528,401

(22) PCT Filed: Feb. 20, 2008
(86) PCT No.: PCT/JP2008/000284

§ 371 Date: Aug. 24, 2009

(30) Foreign Application Priority Data
Feb. 26, 2007 (JP) 2007-046248

(51) Int. Cl. H05K 1/02

(52) U.S. Cl. 174/261

(57) ABSTRACT

An inclined peripheral portion 103 having a tapered shape in a cross-sectional view, in which the thickness thereof is reduced toward the edge of an interconnection substrate 102, is provided at the edge of the interconnection substrate 102. In addition, inner layers 112 are provided such that the distance therebetween is reduced toward the edge of the interconnection substrate in the inclined peripheral portion 103. A first interconnection conductor 104 and a second interconnection conductor 105 are provided on both inclined planes of the inclined peripheral portion 103 so as to be electrically connected to each other at the leading end of the inclined peripheral portion 103.

### TECHNICAL FIELD

The present invention relates to a circuit module obtained by integrating electronic circuits having predetermined functions into a unit, and more particularly, to a high-speed signal module, a high frequency module, and the internal structures thereof.

### BACKGROUND ART

In recent years, circuit modules have been required which are used for, for example, a high-speed signal module and a high frequency module and have electronic circuits accommodated in a smaller space. In order to meet the requirements, the size and space of the modules have been reduced. However, the reduction in the size and space of the module causes the following problems.

First, there is a problem in that unnecessary electromagnetic waves are radiated to the outside of a substrate. In order to reduce the size of the module, an interconnection for connecting mounted parts of an electronic circuit includes, for example, a pad that has a predetermined size for obtaining sufficient strength after soldering and a fine interconnection connected to the pad. In this way, the interconnection having predetermined connection strength is obtained, but the interconnection having predetermined uniform impedance is not necessarily provided as a transmission line. Therefore, the reflection of a high-frequency signal is likely to occur in each portion of the interconnection and the reflected unnecessary high-frequency signal strays in the interconnection substrate, which results in noise and the distortion of a waveform. Therefore, it is an important factor in the design of the module to prevent the reflection of unnecessary high-frequency signals and the like.

In order to achieve the object, generally, the following design method is used. That is, a plurality of ground layers are provided in a substrate, and through holes for electrically connecting and integrating the ground layers to each other are formed in each portion of the substrate. This structure is used to partially shield unnecessary high-frequency signals such that the unnecessary high-frequency signals are not spread to the entire substrate.

However, in the method, there are restrictions in the design of the arrangement of parts. In addition, even when the unnecessary high-frequency signals are partially shielded, the high-frequency signals are repeatedly reflected in the shielded partial space and become standing waves. The standing waves may be radiated as electromagnetic waves to the outside of the substrate through any gap.

For example, Patent Document 1 discloses a method of preventing the radiation of unnecessary electromagnetic waves from the parts mounted in a module and the edge of a substrate. That is, through holes, which are elongated cylindrical conductors, are arranged in a line at a predetermined interval to form a wall, and the wall shields the electromagnetic waves such that the electromagnetic waves are not radiated to the outside. This method is effective in preventing the radiation of the unnecessary electromagnetic waves.

Second, in the case of a module including an antenna part, electromagnetic interference occurs between the antenna part and the other parts mounted on a substrate, and the directivity of the antenna is affected by the electromagnetic interference. In order to solve this problem, Patent Document 1 discloses a structure that shields the transmission path of the antenna and a metal layer for a signal line in the substrate using the through holes and a metal layer for a ground layer to avoid the electromagnetic interference. In addition, Patent Document 2 discloses a structure in which a shield case is divided into two cases and a substrate is covered with the shield case to avoid the electromagnetic interference between an antenna part and the substrate.

[Patent Document 1] JP-A-2003-133801

[Patent Document 2] JP-A-2002-353842

### DISCLOSURE OF THE INVENTION

### Problem to be Solved by the Invention

In particular, for the first problem, a shielding mechanism using the through holes connects the inner interconnections with sufficiently low impedance therebetween. The impedance mismatching causes the total reflection of a high-frequency signal. In order to prevent the radiation of unnecessary electromagnetic waves to the outside it is, particularly, necessary to prevent the radiation of the unnecessary electromagnetic waves from the edge of the substrate to the outside. Therefore, in the related art, a large number of through holes are provided in the outermost circumference of the substrate at very small intervals. In this case, the radiation of the unnecessary electromagnetic waves to the outside is prevented, but the reflected high-frequency signal is repeatedly reflected from the peripheral through hole in the shielded inner space and becomes the standing wave. That is, the energy of the aggressor source is maintained in the substrate and has an adverse effect on the signal of victim load in the shielded space of the substrate.

When there is a standing wave, the eigenfrequency of the victim transmission path of the substrate is equal to the frequency of the standing wave according to the length of the aggressor transmission path, which may cause resonance. In this case, large noise is generated, and various performances of the circuit module are lowered due to the noise. For example, spurious transmission occurs, a carrier-to-noise ratio (C/N ratio) is reduced, reception sensitivity is lowered, and an amplifying ratio becomes insufficient. In recent years, the processing speed and frequency of an electronic circuit have increased, and signal deterioration is likely to occur due to the interference of the electromagnetic wave in the circuit module. In order to prevent the signal deterioration, it is necessary to manufacture a detailed sample for evaluation and repeatedly perform experiments on the sample to verify the design.

In order to improve the efficiency of the mounting design and reduce the development time, it is necessary to quickly integrate electronic circuits having predetermined functions into a module. In this case, the signal performance of each module may not be sufficiently optimized in the development stage due to time restrictions. As a result, the electrical performance of an apparatus is restricted by the performance of the circuit module.

The invention has been made in view of the above-mentioned problems, and an object of the invention is to provide a circuit module capable of effectively preventing the reflection of a high-frequency signal generated in a substrate of the circuit module from the edge of the substrate, the generation of a standing wave from the inside of the substrate, and the radiation of an unnecessary electromagnetic wave from the edge of the substrate to the outside. Another object of the invention is to provide a circuit module capable of effectively preventing electromagnetic interference with an antenna part mounted on the substrate and improving the transmission and reception sensitivities of the antenna or the directivity thereof with a simple structure.

### Means for Solving Problem

A circuit module according to the invention includes an interconnection substrate and parts that are mounted on the interconnection substrate. The interconnection substrate includes: an inclined peripheral portion that is provided at least at a portion of the edge of the interconnection substrate and has a tapered shape in a cross-sectional view in which the thickness is reduced toward the edge; and a plane portion on which the parts are mounted. The distance between a plurality of inner interconnection layers in the interconnection substrate is reduced toward the edge in the inclined peripheral portion.

In the invention, since the gap between the plurality of inner interconnection layers is gradually reduced in the inclined peripheral portion, the impedance therebetween is also gradually reduced without any step difference. In addition, the impedance between the inclined planes of the inclined peripheral portion and the inner layers 112 and the impedance between both inclined planes are also gradually reduced, and the impedance between both inclined planes is reduced toward the edge without any step difference and is approximately zero at the edge. As such, the impedance between the layers is reduced toward the leading end of the inclined peripheral portion 103 without any step difference, which is close to matching at the end. Therefore, according to this embodiment, it is possible to effectively prevent the reflection of a high-frequency signal in the inclined peripheral portion. In this way, it is possible to reduce a standing wave in the interconnection substrate and prevent the radiation of an unnecessary electromagnetic wave to the outside.

In this case, the interconnection substrate may include first and second interconnection conductors that are formed on the front surface and the rear surface of the inclined peripheral portion, respectively, and the first and second interconnection conductors may be electrically connected to each other at the leading end of the inclined peripheral portion.

Another circuit module according to the invention includes an interconnection substrate, and parts that are mounted on the interconnection substrate. The interconnection substrate includes: an inclined peripheral portion that is provided at least at a portion of the edge of the interconnection substrate and has a tapered shape in a cross-sectional view in which the thickness is reduced toward the edge; a plane portion on which the parts are mounted; and first and second interconnection conductors that are formed on a front surface and a rear surface of the inclined peripheral portion, respectively. The first and second interconnection conductors are electrically connected to each other at the leading end of the inclined peripheral portion.

In the invention, the first and second interconnection conductors are provided such that the distance therebetween is gradually reduced to correspond to the tapered shape without any step difference and the first and second interconnection conductors are electrically connected to each other at the leading end of the inclined peripheral portion. Therefore, the impedance between the first and second interconnection conductors is also gradually reduced without any step difference. The first interconnection conductor and the second interconnection conductor are electrically connected to each other at the leading end of the inclined peripheral portion with very small impedance therebetween, which is close to matching at the leading end of the inclined peripheral portion. Therefore, according to this embodiment, it is possible to effectively prevent the reflection of a high-frequency signal in the inclined peripheral portion. As a result, it is possible to reduce the standing wave in the interconnection substrate and prevent the radiation of an unnecessary electromagnetic wave to the outside.

In this case, a through hole may be formed in the plane portion so as to pass through the interconnection substrate in a thickness direction, and a conductor may be inserted into the through hole.

The front and rear surfaces of the inclined peripheral portion may be flat surfaces.

The front and rear surfaces of the inclined peripheral portion may be curved surfaces that are convex to the rear surface and the front surface, respectively.

The interconnection substrate may have a rectangular shape when viewed from above, and the inclined peripheral portion may be provided at one side of the interconnection substrate.

The interconnection substrate may have a rectangular shape when viewed from above, and the inclined peripheral portions may be provided at a pair of opposite sides of the interconnection substrate.

The part may be mounted on at least one of the front surface and the rear surface of the inclined peripheral portion.

The part mounted on at least one of the front surface and the rear surface of the inclined peripheral portion may be an antenna part. According to this structure, the angle formed between the inclined plane of the inclined peripheral portion and the plane portion of the interconnection substrate having the parts mounted thereon is greater than 180 degrees. Therefore, it is possible to obtain the same effect as that of arranging the antenna part at a position spaced from the mounted parts. That is, it is possible to arrange the antenna part such that the directivity thereof is not affected by the mounted parts.

The circuit module may further include a shield case that is provided so as to cover the parts mounted on the plane portion and is electrically connected to the first interconnection conductor or the second interconnection conductor.

### Effects of the Invention

According to the invention, it is possible to provide a circuit module capable of effectively preventing the reflection of a high-frequency signal generated in a substrate of the circuit module from the edge of the substrate, the generation of a standing wave from the inside of the substrate, and the radiation of an unnecessary electromagnetic wave from the edge of the substrate to the outside. In addition, it is possible to provide a circuit module capable of effectively preventing electromagnetic interference with an antenna part mounted on the substrate and improving the transmission and reception sensitivities of the antenna or the directivity thereof with a simple structure.

### BRIEF DESCRIPTION OF THE DRAWINGS

The above-mentioned objects, other objects, features, and advantages will become apparent from the following exemplary embodiments and the following accompanying drawings.

FIG. 1 is a cross-sectional view illustrating a circuit module according to a first embodiment of the invention.

FIG. 2 is a cross-sectional view illustrating a circuit module according to a second embodiment of the invention.

FIG. 3 is a cross-sectional view illustrating a circuit module according to a third embodiment of the invention.

FIG. 4 is a cross-sectional view illustrating a circuit module according to a fourth embodiment of the invention.

FIG. 5 is a cross-sectional view illustrating a circuit module according to a fifth embodiment of the invention.

FIGS. 6(a) and 6(b) are a cross-sectional view and a plan view illustrating a circuit module according to a sixth embodiment of the invention, respectively.

FIGS. 7(a) and 7(b) are a cross-sectional view and a plan view illustrating a circuit module according to a seventh embodiment of the invention, respectively.

FIG. 8 is a cross-sectional view illustrating a circuit module according to an eighth embodiment of the invention.

FIG. 9 is a cross-sectional view illustrating a circuit module according to a ninth embodiment of the invention.

FIG. 10 is a cross-sectional view illustrating a circuit module according to a tenth embodiment of the invention.

FIG. 11 is a cross-sectional view illustrating a circuit module according to an eleventh embodiment of the invention.

### BEST MODE FOR CARRYING OUT THE INVENTION

Hereinafter, exemplary embodiments of the invention will be described in detail with reference to the accompanying drawings. In the drawings, the same components are denoted by the same reference numerals, and a repeated description thereof will be omitted.

### First Embodiment

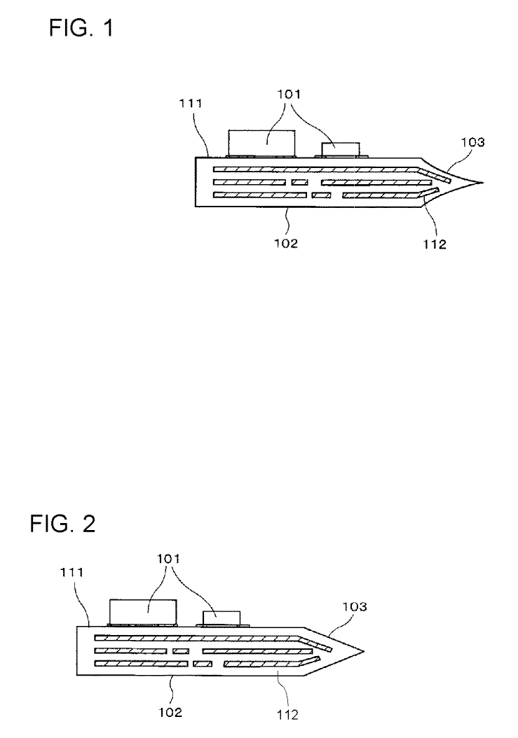

First, a first embodiment of the invention will be described. This embodiment includes an interconnection substrate and parts mounted on the interconnection substrate. FIG. 1 is a cross-sectional view illustrating a circuit module according to this embodiment.

As shown in FIG. 1, an interconnection substrate 102 includes a plane portion 111 and an inclined peripheral portion 103. Parts 101 are mounted on the plane portion 111. In FIG. 1, one inclined peripheral portion 103 is provided at the edge of the interconnection substrate 102 and has a curved tapered shape in which the thickness of the inclined peripheral portion is gradually reduced toward the edge. A plurality of inner layers 112 is formed in the interconnection substrate 102. The inner layers 112 are made of a metal material having high conductivity, such as Cu. The inner layers 112 are provided such that the distance therebetween is gradually reduced toward the edge of the interconnection substrate 102 in the inclined peripheral portion 103.

Next, the operation of the circuit module according to this embodiment will be described. In general, when there is a step difference in the impedance of a transmission path in the substrate, a high-frequency signal is reflected from the step portion, and the reflected signal strays in the substrate. When the reflected signal is reflected again from the reflection side, that is, when multiple reflection occurs, the reflection signal exists as a standing wave in the substrate. In this case, the reflected signal has an adverse effect on the performance of the circuit module. That is, the reflected signal causes noise or the distortion of a waveform. In addition, in some cases, the standing wave is radiated as an unnecessary electromagnetic wave to the outside of the substrate and has an adverse effect on an external apparatus.

In the module according to this embodiment, the high-frequency signal generated by an electronic circuit is transmitted to the inner layers 112 and travels toward the edge of the substrate. Since the gap between the inner layers 112 is gradually reduced in the inclined peripheral portion 103, the impedance between the inner layers is also gradually reduced without any step difference. In addition, the impedance between the inclined planes of the inclined peripheral portion 103 and the inner layers 112 and the impedance between both inclined planes are also gradually reduced, and the impedance between both inclined planes is reduced toward the edge without any step difference and is approximately zero at the edge. As such, the impedance between the inner layers is reduced toward the leading end of the inclined peripheral portion 103 without any step difference, which is close to matching at the end. Therefore, according to this embodiment, it is possible to effectively prevent the reflection of a high-frequency signal in the inclined peripheral portion 103. In this way, it is possible to reduce the standing wave in the interconnection substrate 102 and prevent the radiation of an unnecessary electromagnetic wave to the outside.

### Second Embodiment

Next, a second embodiment of the invention will be described. FIG. 2 is a cross-sectional view illustrating a circuit module according to this embodiment. In the circuit module according to this embodiment, the inclined peripheral portion 103 includes a flat front surface and a flat rear surface. The other structures of this embodiment are the same as those of the first embodiment.

In order to prevent the reflection of a high-frequency signal in the inclined peripheral portion 103, it is ideal that the cross-section of the inclined peripheral portion is tapered so as to draw an exponential curve. This means that the inner layers 112 draw the same curve as the inclined peripheral portion such that the distance therebetween is gradually reduced when the interconnection substrate 102 is formed. However, when the inclined peripheral portion is tapered in the curved shape, the leading end of the inclined peripheral portion 103 may be excessively sharp depending on the structure of the substrate, which is not preferable in terms of manufacture and treatment. Therefore, in this embodiment, the front surface and the rear surface of the inclined peripheral portion 103 are flat. In this case, similarly, the distance between the inner layers 112 is gradually reduced toward the outer circumference of the substrate. Therefore, it is possible to obtain a circuit module that is easily treated and is capable of preventing the reflection of a high-frequency signal. In addition, the structure according to this embodiment makes it easy to mount parts on the inclined plane of the inclined peripheral portion 103.

### Third Embodiment

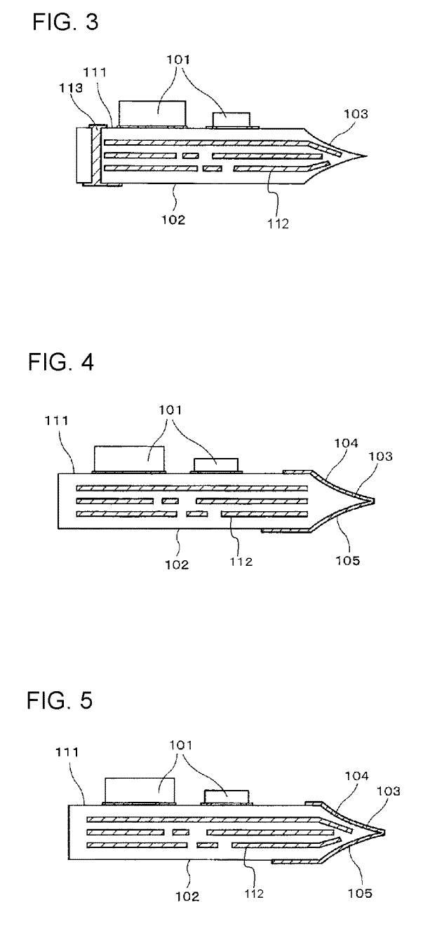

Next, a third embodiment of the invention will be described. FIG. 3 is a cross-sectional view illustrating a circuit module according to this embodiment. In the circuit module according to this embodiment, a through hole 113 is formed at the edge of the interconnection substrate 102 other than the inclined peripheral portion 103 so as to pass through the interconnection substrate 102 in the thickness direction. The other structures of this embodiment are the same as those of the first embodiment.

The through hole 113 is provided in order to connect different layers in a multi-layer substrate. When the layers are connected to each other, the impedance of a connection portion is sufficiently less than that between the layers in the substrate. Therefore, the through hole 113 has a shielding effect of totally reflecting the high-frequency signal transmitted to an interconnection in the substrate. According to this embodiment, the through hole 113 formed at the edge of the interconnection substrate other than the inclined peripheral portion 103 can prevent the reflection of the high-frequency signal and the radiation of an unnecessary electromagnetic wave from the edge of the substrate. In addition, as described above, the reflected high-frequency signal is prevented from being reflected from the inclined peripheral portion 103. Therefore, it is possible to prevent the reflected high-frequency signal from serving as a standing wave in the substrate due to multiple reflection.

### Fourth Embodiment

Next, a fourth embodiment of the invention will be described. FIG. 4 is a cross-sectional view illustrating a circuit module according to this embodiment. In the circuit module according to this embodiment, the inner layers 112 are provided in the interconnection substrate 102 so as to have a constant distance therebetween. In addition, in FIG. 4, a first interconnection conductor 104 is formed on the upper surface of the inclined peripheral portion 103. A second interconnection conductor 105 is formed on the lower surface of the inclined peripheral portion 103. The first interconnection conductor 104 and the second interconnection conductor 105 are made of the same metal material as that forming the other interconnections provided in the interconnection substrate 102. The first interconnection conductor 104 and the second interconnection conductor 105 are electrically connected to each other at the leading end of the inclined peripheral portion 103. The other structures of this embodiment are the same as those of the first embodiment.

In this embodiment, the first interconnection conductor 104 and the second interconnection conductor 105 are excited by the inner layers 112, and a high-frequency signal in the substrate is transmitted. The high-frequency signal is transmitted to the edge of the substrate in the first interconnection conductor 104 and the second interconnection conductor 105. The distance between the first interconnection conductor 104 and the second interconnection conductor 105 is gradually reduced to correspond to the tapered shape without any step difference. Therefore, the impedance between the first and second interconnection conductors is also gradually reduced without any step difference. The first interconnection conductor 104 and the second interconnection conductor 105 are electrically connected to each other at the leading end of the inclined peripheral portion 103. Since the first interconnection conductor 104 and the second interconnection conductor 105 are connected to each other with a very small impedance therebetween, the effect similar to the matching at the leading end of the inclined peripheral portion 103 is obtained, similar to the first embodiment. Therefore, according to this embodiment, the high-frequency signal is not reflected inward, and it is possible to prevent the high-frequency signal from serving as the standing wave.

### Fifth Embodiment

Next, a fifth embodiment of the invention will be described. FIG. 5 is a cross-sectional view illustrating a circuit module according to this embodiment. In the circuit module according to this embodiment, similar to the first embodiment, the inner layers 112 are provided such that the distance therebetween is reduced toward the edge of the inclined peripheral portion 103. The other structures of this embodiment are the same as those of the fourth embodiment.

In this embodiment, similar to the first embodiment, it is possible to gradually reduce the characteristic impedance between the inner layers 112 without any step difference. In this way, according to this embodiment, it is possible to obtain the effect of preventing the reflection of a high-frequency signal in the substrate. In addition, in this embodiment, it is possible to obtain the effect of more effectively preventing the reflection of the high-frequency signal in addition to the effects of the fourth embodiment.

### Sixth Embodiment

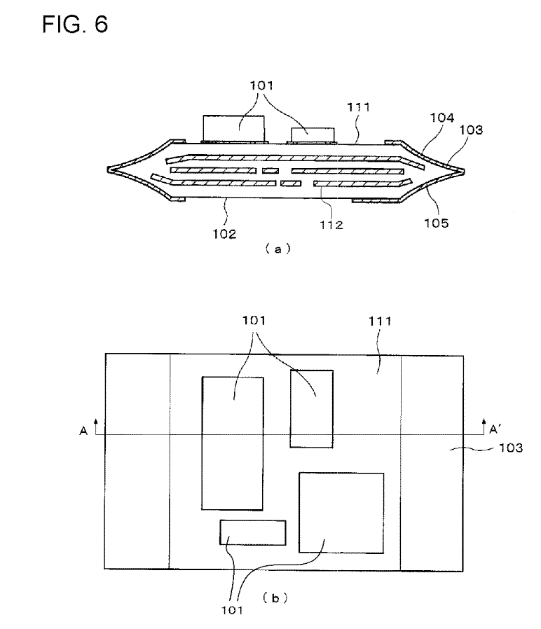

Next, a sixth embodiment of the invention will be described. FIGS. 6(a) and 6(b) are a cross-sectional view and a plan view illustrating a circuit module according to this embodiment, respectively. FIG. 6(a) is a cross-sectional view taken along the line A-A′ of FIG. 6(b). In the circuit module according to this embodiment, the interconnection substrate 102 has a rectangular shape when viewed from above, and the inclined peripheral portions 103 are provided at a pair of opposite sides of the interconnection substrate 102. In addition, the first interconnection conductor 104 and the second interconnection conductor 105 are provided in each of the inclined peripheral portions 103. The other structures of this embodiment are the same as those of the fifth embodiment.

The effect of preventing the reflection of a high-frequency signal in the inclined peripheral portion 103 is the same as that in the fifth embodiment. In this embodiment, the inclined peripheral portions 103 provided at a pair of opposite sides of the substrate make it possible to prevent the reflection of the high-frequency signal. Therefore, in this embodiment, it is possible to more effectively reduce the standing wave in the interconnection substrate 102 and prevent the radiation of an unnecessary electromagnetic wave from the edge of the substrate.

### Seventh Embodiment

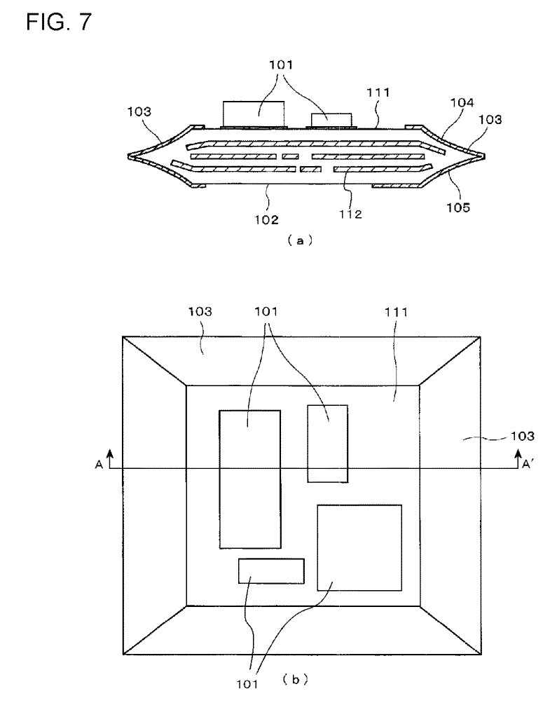

Next, a seventh embodiment of the invention will be described. FIGS. 7(a) and 7(b) are a cross-sectional view and a plan view illustrating a circuit module according to this embodiment, respectively. FIG. 7(a) is a cross-sectional view taken along the line A-A′ of FIG. 7(b) In the circuit module according to this embodiment, the inclined peripheral portions 103 are provided at two pairs of sides of the interconnection substrate 102 having a rectangular shape. That is, the inclined peripheral portions 103 are provided at the entire edge of the interconnection substrate. In addition, the first interconnection conductor 104 and the second interconnection conductor 105 are provided in each of the inclined peripheral portions 103. The other structures of this embodiment are the same as those of the sixth embodiment.

The effect of this embodiment is the same as that of the sixth embodiment. It is possible to more effectively prevent the reflection of a high-frequency signal from the edge of the substrate by increasing the number of inclined peripheral portions 103. The effect of preventing the radiation of an unnecessary electromagnetic wave is also obtained. In this embodiment, the interconnection substrate 102 having a rectangular shape is used for simplicity. However, the inclined peripheral portions 103 may be provided at two or more pairs of opposite sides of the interconnection substrate 102 having other shapes.

### Eighth Embodiment

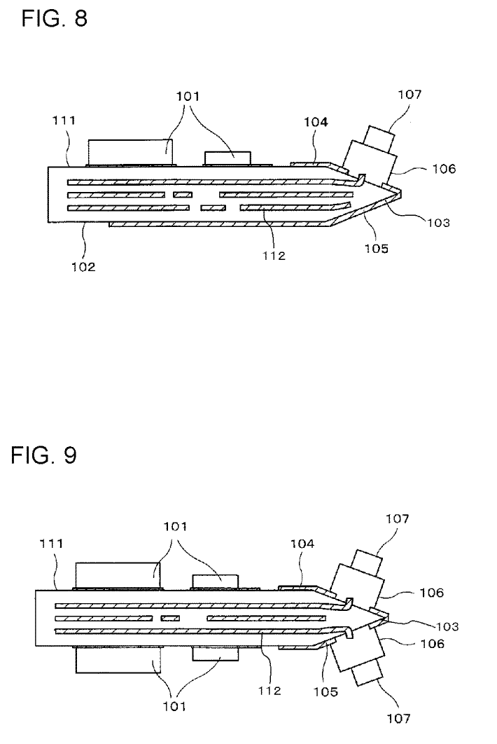

Next, an eighth embodiment of the invention will be described. FIG. 8 is a cross-sectional view illustrating a circuit module according to this embodiment. In the circuit module according to this embodiment, the front surface and the rear surface of the inclined peripheral portion 103 are flat such that parts are easily mounted on the front and rear surfaces. A connector 106 is provided on the upper inclined plane in FIG. 8. An antenna part 107 is provided on the connector 106 and is connected to an inner interconnection layer 112 of the interconnection substrate 102. The other structures of this embodiment are the same as those of the fifth embodiment.

In this embodiment, the angle formed between the inclined plane of the inclined peripheral portion 103 and the surface of the plane portion 111 is greater than 180 degrees. Therefore, according to this embodiment, the same effect as that of arranging the antenna part 107 at a position spaced from mounted parts 101 is obtained. That is, it is possible to prevent the electromagnetic interference between the antenna part 107 and the mounted parts 101 and arrange the antenna part 107 such that the directivity thereof is not affected by the mounted parts 101.

### Ninth Embodiment

Next, a ninth embodiment of the invention will be described. FIG. 9 is a cross-sectional view illustrating a circuit module according to this embodiment. In the circuit module according to this embodiment, the connector 106 and the antenna part 107 are provided on each of the front surface and the rear surface of the inclined peripheral portion 103. In addition, parts 101 are mounted on the upper and lower surface of the plane portion 111. The other structures of this embodiment are the same as those of the eighth embodiment.

In this embodiment, two antenna parts 107 are provided on the upper and lower tapered surfaces. Therefore, the angle formed between the centers of the antenna parts 107 is less than 180 degrees with respect to a horizontal line passing through the leading end of the inclined peripheral portion 103 in FIG. 9. Therefore, it is particularly possible to eliminate blind spots in the sensitivity of the two antennas, particularly, in the horizontal direction of the substrate. In addition, when the antenna has a diversity function, it is possible to improve a switching performance in the horizontal direction of the substrate.

In this embodiment, the connectors 106 and the antenna parts 107 are provided on the inclined peripheral portion 103, but the invention is not limited thereto. For example, instead of the antenna, a microphone may be provided. The arrangement of the microphone may be the same as that of the antenna shown in FIG. 9, or the microphone may be arranged on one of the front inclined surface and the rear inclined surface of the inclined peripheral portion 103.

### Tenth Embodiment

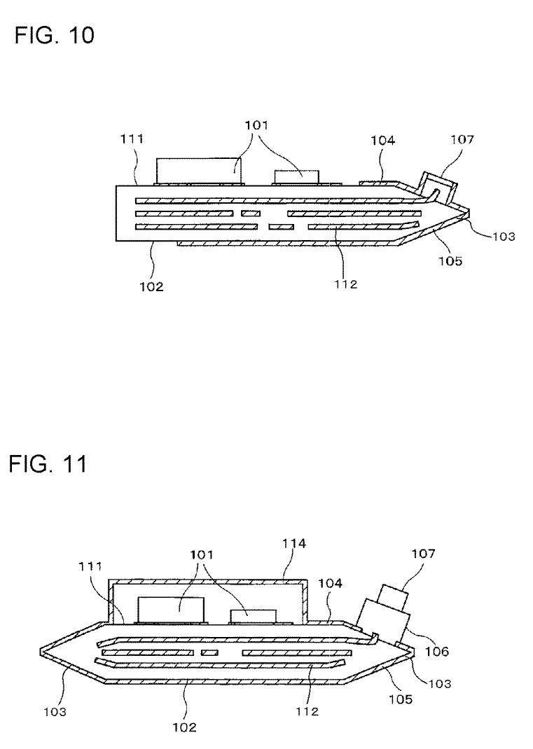

Next, a tenth embodiment of the invention will be described. FIG. 10 is a cross-sectional view illustrating a circuit module according to this embodiment. In the circuit module according to this embodiment, the antenna part 107 is mounted on the tapered surface of the inclined peripheral portion 103 without a connector interposed therebetween. The other structures and effects of this embodiment are the same as those of the eighth embodiment.

### Eleventh Embodiment

Next, an eleventh embodiment of the invention will be described. FIG. 11 is a cross-sectional view illustrating a circuit module according to this embodiment. In the circuit module according to this embodiment, a shield case 114 is provided on the interconnection substrate 102 so as to cover the mounted parts 101. The shield case 114 is made of a metal material such as Cu. The shield case 114 is electrically connected to the first interconnection conductor 104 and the second interconnection conductor 105. The other structures of this embodiment are the same as those of the seventh embodiment.

In this embodiment, the shield case 114 shields electromagnetic waves to prevent the electromagnetic interference between the mounted parts 101 and the antenna part 107 or an external apparatus. In addition, it is possible to obtain the effect of effectively preventing the electromagnetic interference between the parts or between the parts and an external apparatus, in addition to the effects of the seventh embodiment.

In this embodiment, the shield case 114 is provided so as to cover all the mounted parts 101, but the invention is not limited thereto. For example, the shield case 114 may be provided so as to individually cover the mounted parts 101 or cover a plurality of mounted parts 101.

### INDUSTRIAL APPLICABILITY

The invention can be appropriately used for circuit modules such as a high-speed signal module and a high-frequency module.

1. A circuit module comprising:
an interconnection substrate; and
parts that are mounted on said interconnection substrate,
wherein said interconnection substrate includes:
an inclined peripheral portion that is provided at least at a portion of the edge of said interconnection substrate and has a tapered shape in a cross-sectional view in which the thickness is reduced toward the edge; and
a plane portion on which said parts are mounted, and
a distance between a plurality of inner interconnection layers in said interconnection substrate is reduced toward said edge in said inclined peripheral portion.

2. A circuit module comprising:
an interconnection substrate; and
parts that are mounted on said interconnection substrate,
wherein said interconnection substrate includes:
an inclined peripheral portion that is provided at least at a portion of the edge of said interconnection substrate and has a tapered shape in a cross-sectional view in which the thickness is reduced toward the edge;
a plane portion on which said parts are mounted; and
first and second interconnection conductors that are formed on a front surface and a rear surface of said inclined peripheral portion, respectively, and
said first and second interconnection conductors are electrically connected to each other at the leading end of said inclined peripheral portion.

3. The circuit module according to claim 1,
wherein a through hole is formed in said plane portion so as to pass through said interconnection substrate in a thickness direction, and a conductor is inserted into said through hole.

4. The circuit module according to in claim 1,
wherein said interconnection substrate includes first and second interconnection conductors that are formed on a front surface and a rear surface of said inclined peripheral portion, respectively, and
said first and second interconnection conductors are electrically connected to each other at the leading end of said inclined peripheral portion.

5. The circuit module according to claim 1,
wherein the front and rear surfaces of said inclined peripheral portion are flat surfaces.

6. The circuit module according to claim 1,
wherein the front and rear surfaces of said inclined peripheral portion are curved surfaces that are convex to the rear surface and the front surface, respectively.

7. The circuit module according to claim 1,
wherein said interconnection substrate has a rectangular shape when viewed from above, and
said inclined peripheral portion is provided at one side of said interconnection substrate.

8. The circuit module according to claim 1,
wherein said interconnection substrate has a rectangular shape when viewed from above, and
said inclined peripheral portions are provided at a pair of opposite sides of said interconnection substrate.

9. The circuit module according to claim 1,
wherein said part is mounted on at least one of the front surface and the rear surface of said inclined peripheral portion.

10. The circuit module according to claim 9,
wherein said part mounted on at least one of the front surface and the rear surface of said inclined peripheral portion is an antenna part.

11. The circuit module according to claim 4, further comprising:
a shield case that is provided so as to cover the parts mounted on said plane portion and is electrically connected to said first interconnection conductor or said second interconnection conductor.

12. The circuit module according to claim 2,
wherein a through hole is formed in said plane portion so as to pass through said interconnection substrate in a thickness direction, and a conductor is inserted into said through hole.

13. The circuit module according to claims 2,
wherein the front and rear surfaces of said inclined peripheral portion are flat surfaces.

14. The circuit module according to claims 2,
wherein the front and rear surfaces of said inclined peripheral portion are curved surfaces that are convex to the rear surface and the front surface, respectively.

15. The circuit module according to claims 2,
wherein said interconnection substrate has a rectangular shape when viewed from above, and
said inclined peripheral portion is provided at one side of said interconnection substrate.

16. The circuit module according to claims 2,
wherein said interconnection substrate has a rectangular shape when viewed from above, and
said inclined peripheral portions are provided at a pair of opposite sides of said interconnection substrate.

17. The circuit module according to claims 2,
wherein said part is mounted on at least one of the front surface and the rear surface of said inclined peripheral portion.

18. The circuit module according to claim 17,
wherein said part mounted on at least one of the front surface and the rear surface of said inclined peripheral portion is an antenna part.

19. The circuit module according to claim 2, further comprising:
a shield case that is provided so as to cover the parts mounted on said plane portion and is electrically connected to said first interconnection conductor or said second interconnection conductor.
